(19) United States
(12) Patent Application Publication
(10) Pub. No.: US 2011/0100463 A1
(43) Pub. Date: May 5, 2011

(54) SOLAR POWER GENERATION USING PHOTOSYNTHESIS

(75) Inventor: Ami Elazari, Tel-Aviv (IL)

(73) Assignee: T.O.U. MILLENNIUM ELECTRIC LTD., RaAnana (IL)

(21) Appl. No.: 12/450,202

(22) PCT Filed: Mar. 16, 2008
(86) PCT No.: PCT/IL2008/000369

§ 371 Date: Dec. 14, 2010

Related U.S. Application Data
(60) Provisional application No. 60/907,008, filed on Mar. 16, 2007.

(51) Int. Cl. H01L 51/46; H01M 6/30

(52) U.S. Cl. 136/263; 429/111

(57) ABSTRACT

Photovoltaic cell apparatus comprises a first electrode; photosynthetic material electrically connected to the first electrode; and a second electrode electrically connected to the photosynthetic material. The electrodes are able to harvest electrons from the photosynthetic material.

### FIELD AND BACKGROUND OF THE INVENTION

The present invention, in some embodiments thereof, relates to a method and apparatus for solar power generation based on photosynthesis and a manufacturing method for making such apparatus, also genetically engineered plant material for use in the same.

Light energy is cheap, clean, and essentially inexhaustible. With limited supplies of fossil fuel and increasing concern about CO2 emissions, further development of technologies that make use of solar energy is inevitable. Current silicon-based technologies for the harvesting of solar energy require a very energy-intensive production process and even though they have improved significantly over the years in their efficiency, further development of photosynthesis-based technologies for energy collection is certainly warranted. However, photosynthesis and related processes can be applied to many more areas than just solar energy conversion, and novel designs and applications of light-mediated processes have enormous promise and potential in the next decade and beyond.

Solar cells or photovoltaic cells (PVC), are optoelectronic devices that convert sunlight to electrical power. The use of PVC as an alternative source for renewable energy is important because of the increasing cost of fossil oil, the adverse effect of pollution on health and on the environment and the ever increasing depletion of the planet's oil reserves. The use of PVC as a renewable energy source is growing at an estimated 35% a year at in the world market. Current technology uses silicon-based PVC with an average energy conversion efficiency of 12-18%. Future technologies include the use of expensive GaAs and multi junctions that have attained ˜40% efficiency but are relatively expensive to manufacture, and dye and polymer PVCs which yield much lower efficiency than silicon cells but are less expensive. The known devices of these devices are thus not sufficiently cost effective, and it remains an aim to design a device which is both efficient and cheap.

One source of solar energy is photosynthesis. Electrons drained from the photosynthetic electron transport chain represent a form of electricity. The technology for draining-off electrons from the photosynthetic chain has long been available in the academic domain. The use of various electron acceptors, characterised by distinct binding sites in the photosynthetic chain, has been extensively exploited in the past to study the process of photosynthesis. Typical, well-characterised compounds capable of accepting electrons are ferricyanide, p-phenylenediamine, silicomolybdate and 3,6 diaminodurol. Methylviologen in particular is known to effectively catalyse the transfer of electrons from a binding site near PS I to the electron acceptor molecular oxygen, in the process regenerating itself. Often these artificial compounds accept electrons from molecular sites that have evolved to accommodate native electrons transport compounds that are an intrinsic part of the electron transport chain.

### SUMMARY OF THE INVENTION

The present invention in some embodiments comprises a photovoltaic cell containing a nanometric biological photosynthetic reaction center protein, photosystem I (PS I), as a photoactive component. The embodiments take advantage of this capability of the photosynthetic system to transfer electrons to mobile carriers, and then use efficient electron shuttles to transfer electrons to electricity conducting elements

According to an aspect of some embodiments of the present invention there is provided photovoltaic cell apparatus comprising:
a first electrode;
photosynthetic material electrically connected to said first electrode; and
a second electrode electrically connected to said photosynthetic material, said apparatus thereby providing the harvesting of electrons from said photosynthetic material.

In an embodiment, said photosynthetic material is located in a cavity of a semiconductor.

In an embodiment, said second electrode is transparent.

In an embodiment, said photosynthetic material comprises PS I material.

In an embodiment, said photosynthetic material is genetically engineered to pass a first proportion of photosynthesis excitation electrons to said electrodes.

In an embodiment, said photosynthetic material is genetically engineered to retain a second proportion of said photosynthesis excitation electrons for sugar production.

In an embodiment, said cavity is drilled into said semiconductor layer.

In an embodiment, said first electrode is arranged as a grid, reaching a plurality of said cavities about said apparatus.

In an embodiment, said first electrode comprises gold.

In an embodiment, said grid, said cavities and said second electrode are arranged as a first layer therein.

In an embodiment, said grid, said cavities and said second electrode are arranged as a plurality of layers.

An embodiment may be configured for attachment to a growing plant as a patch.

An embodiment may comprise a mechanism for collecting released oxygen and hydrogen molecules.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified schematic diagram showing the photo-electronic properties of PS I;

FIG. 2 is a simplified diagram showing a single cell of a PSI photovoltaic device according to a first preferred embodiment of the present invention;

FIG. 3 is a simplified diagram illustrating a device constructed from the cells of FIG. 2;

FIG. 4 is a simplified diagram illustrating the modified photosynthetic process of plant material genetically modified according to the present embodiments;

FIGS. 5A, 5B, 6 and 7 are schematic diagrams illustrating regular photosynthesis;

FIG. 8 is a simplified diagram illustrating the use of the present embodiments for micro-level power generation; and

FIG. 9 is a simplified diagram illustrating the user of the present embodiments for macro-level power generation.

### DESCRIPTION OF EMBODIMENTS OF THE INVENTION

The present invention, in some embodiments thereof, relates to a method and apparatus for solar power generation based on photosynthesis and a manufacturing method for making such an apparatus, also genetically engineered plant material for use in the same.

The present embodiments provide a new source of natural energy (electricity) by photosynthesis, which is obtained directly from living plant material. The electricity capacity may be evaluated based on the nature of the given plant, and the time and intensity of any sunlight exposure.

The present embodiments comprise a new method for electricity current collection, based on placing micro-electrophysiology patches on the plant itself, that is to say on the leaf. The patches may be optimized for any given plant crop.

Further embodiments provide a genetically engineered plant for high efficiency electricity current release.

The present embodiments may provide a photosynthetic plant extract, that may be incubated in the sunlight, in which a genetically improved electron transport chain (E-chain) linked into a semiconductor element via an electron carrier protein (E-protein) may transport sunlight-excited electrons to generate electricity. The input of the system is sunlight, soil and water, while its output is electric power. The by-products, oxygen and hydrogen, may be collected for industrial use, and discharged plant extracts may be transformed to a fertiliser for crop farming. Thus, the present embodiments show sustainability—are completely free from any pollutants—and make up a beneficial life cycle.

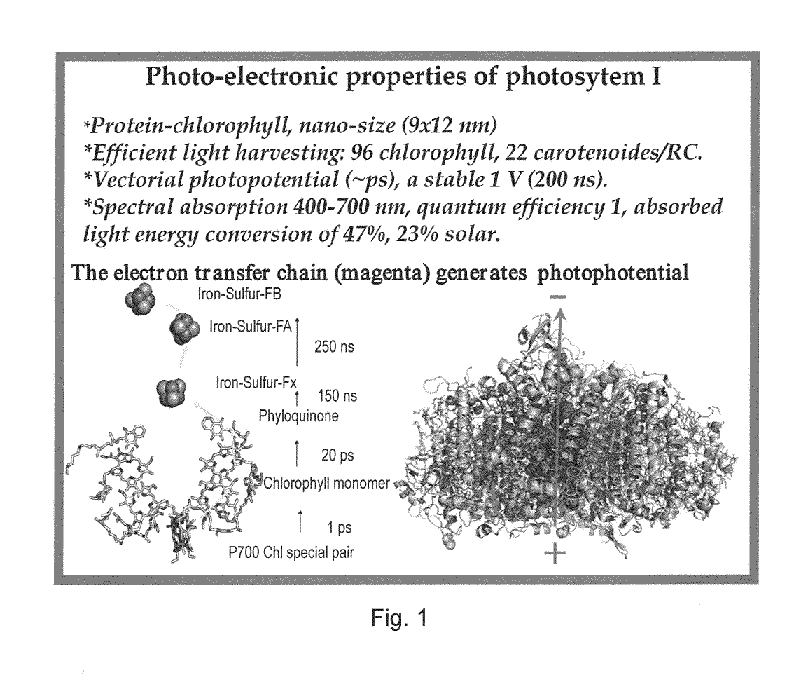

As well as a patch, the present embodiments comprise a PVC containing the nanometric biological photosynthetic reaction center protein, photosystem I (PS I), as a photoactive component. PS I is a transmembrane multisubunit protein-chlorophyll complex that mediates vectorial light-induced electron transfer. PS I generates a stable charge separation in 200 ns across 6 nm of protein to generate an electric potential of 1 V with quantum efficiency of 1 and absorbed energy conversion efficiency of 47%, see FIG. 1. PS I absorbs 53% of the sun irradiance between 400-700 nm, resulting in total sun irradiance energy conversion efficiency of 23% in cyanobacteria.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Referring now to the drawings, FIG. 1 illustrates a molecular image of PS I showing the protein chains in ribbons, the chlorophylls in green and the electron transfer chain.

The present embodiments exploit the properties of these inexpensive and available systems by integrating them inside conventional solid-state templates. In order to use the PS I in PVCs, we take the relatively robust PS I from cyanobacteria. Genetic engineering technology may be used to induce unique cysteine mutants that enable covalent binding of PS I to metal surfaces resulting in a self-assembled oriented monolayer.

Nanotechnological methodology may be utilized for the fabrication and the determination of the function and efficiency of the devices.

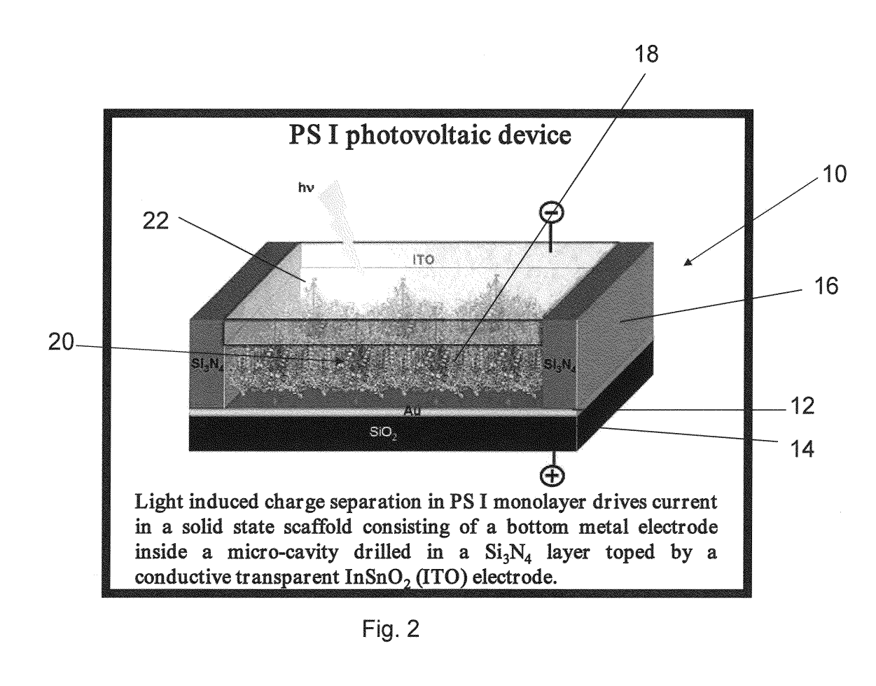

Reference is now made to FIG. 2, which illustrates a solid state device fabricated in accordance with the above, in which the self-assembled monolayer was encapsulated in an array of controlled micro-cavities. The device consists of a nanometric oriented dry layer of the photosynthetic reaction center protein bound to a bottom metal electrode and an upper transparent electrode.

As shown in FIG. 2, a photovoltaic cell 10 according to the present embodiments comprises a first electrode 12, located over a layer of insulator 14. the first electrode 12 may be of gold or any other high quality conductor. The layer of insulator is here shown as silicon dioxide. A second silicon layer 16, Si₃N₄, has cavities 18 formed therein into which photosynthetic material 20 is placed. The photosynthetic material includes at least the PSI part, but may additionally include PSII material.

A second electrode 22 is placed over the cavity. A charge is placed across the electrodes and the photosynthetic material is able to self-orientate between the electrodes and form covalent bonds therewith. The electrons are thereafter able to harvest electrons from the photosynthetic material. The photosynthetic material may be a nanometric self-oriented dry layer of the photosynthetic reaction center protein. The second electron is preferably transparent, especially to those wavelengths which are most important for photosynthesis. A suitable material is indium tin oxide InSnO₂ or ITO. Indium oxide doped with tin oxide, ITO, is used to make transparent conductive coatings. Thin film layers can be deposited by electron-beam evaporation or sputtering.

The photosynthetic material is located in the cavity 16 prior to application of the ITO to form the upper electrode. Once the upper electrode is in place and a voltage applied, the photosynthetic material self-orientates.

The photosynthetic material is genetically engineered to pass a first proportion of photosynthesis excitation electrons to the electrodes. The photosynthetic material is genetically engineered to retain a second proportion of the photosynthesis excitation electrons for sugar production, for self-preservation.

The cavity 18 may be drilled into the semiconductor layer, or may be etched or formed in any of the standard ways for providing cavitation in semiconductor material. Typical sizes for the cavity are from one square microns to tens of square centimeters. The experiment described below used a size of 3 square microns but any size that allows for self-orientation of the photosynthetic material may be used.

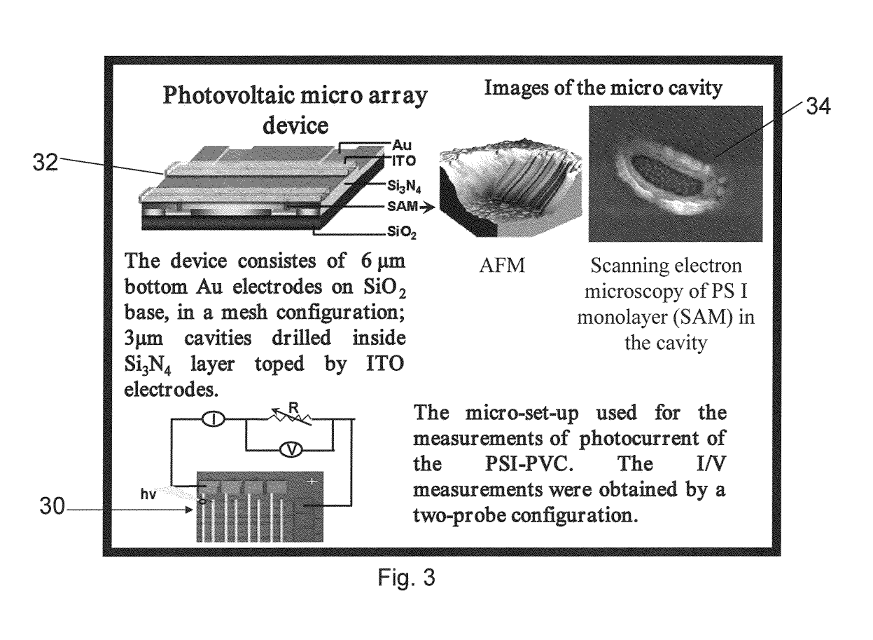

Referring now to FIG. 3, the first electrode 12 may be arranged as a grid 30, over which numerous cavities are filled with photosynthetic material. The grid 30, the cavities 16 and the second electrode 22 are arranged as a first layer or monolayer 32.

Several such monolayers may form a multi-layer device. Up to a certain extent adding layers improves efficiency, but beyond a certain level efficiency drops as the amount of irradiation is reduced due to the upper layers. The skilled person will thus find the optimal number of layers in any given circumstance. The optimal number of layers may differ in different climates, since higher levels of solar radiation, associated with hot countries, comprise more photons, so that the probability of a photon penetrating to the nth layer is higher.

Insert 34 is a scanning electron micrograph of PSI material in the cavity.

In an embodiment, the device of the present embodiment is applied as a patch or an insert onto the photosynthesizing leaf of a growing plant.

A gas collection mechanism may be provided to tap the oxygen and hydrogen produced by photosynthesis.

In experiments the device 10 was irradiated with sunlight, and a light induced photocurrent of 0.7 mA at 0.2 V at an absorbed energy conversion efficiency of 34% was observed. The PVC was stable for the test period of one year. It is noted that in general, dry proteins which are functional for a year are expected to remain stable for many years. The high efficiency of light energy conversion indicates a good photoelectronic function of the reaction center protein and little energy loss in the electrical junctions of the device. The total light absorbed by a thin layer of the active photoelectric component is low and therefore the energy conversion efficiency of the incident light is 0.7%. The stacking of many nanometric layers may increase the total absorption and the total energy conversion efficiency of the device.

A further embodiment comprises a methodology to fabricate functional oriented multilayers by sequential binding and platinization of PS I. The multilayers achieve an increase in photovoltage over the monolayers, due to increased light absorption and the sequential arrangement of the PS I.

These results indicate that the robust PS I from cyanobacteria can be used as a photoactive component in a solid state template that will lead toward the development of a cost effective bio-nano-photoelectric device (BIOPV).

Development of the PS I multilayer embodiment comprises increasing the number of layers, testing various metal junctions and fabrication of devices with increasing layers of PS I.

In embodiments, the size of the PVC cavities may reach between 1 and 3 mm² and testing of efficiency with various metals and transparent electrodes in the multilayer devices.

In embodiments, the size of the PVC cavities may reach up to 1 cm² or 1×20 mm, on tending towards total light absorption by multilayers of PS I, and on the construction of array of multiple 1 cm² devices.

Genetic Modification Artificial Photosynthesis

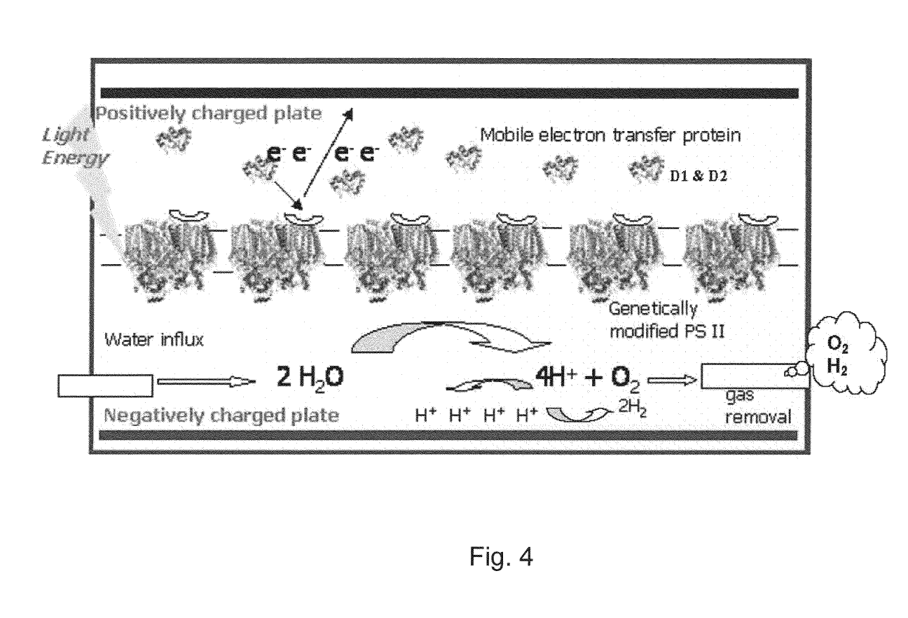

Reference is now made to FIG. 4, which is a simplified diagram showing the photosynthesis procedure as modified by genetic engineering, to allow making electricity by connecting leaf cells of transgenic plants to form photovoltaic cells. The previous discussion involved cyanobacteria. In the following the tobacco plant is discussed. Transgenic tobacco plants may be produced in which the thylakoid photosystem II proteins (D1 and D2) are genetically modified in such a way that a high binding affinity site may be introduced in a closed vicinity to the plastoquinone binding site. Crude thylakoid leaf cells of these plants may be connected in strings between two large electrode patches and supplied with a highly efficient soluble electron carrier protein (E-protein). Upon charging the electrodes and irradiating with light, which may be sun light, electron transfer takes place between the patches.

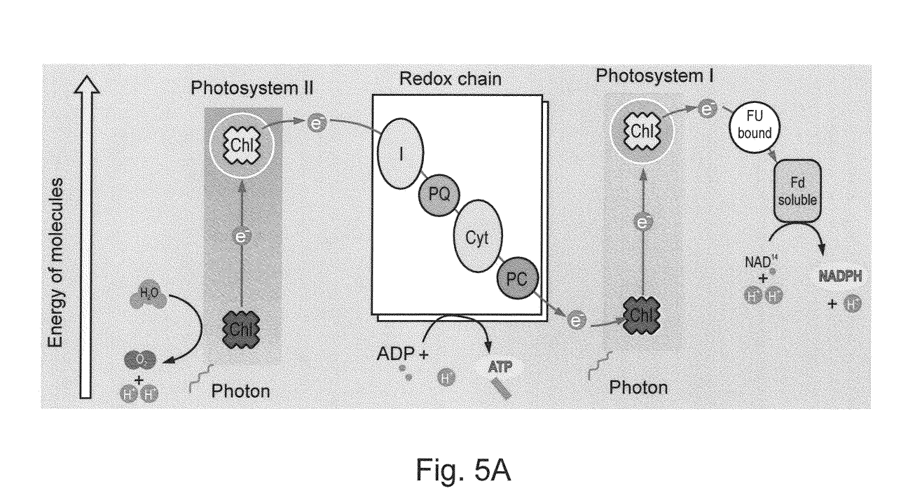

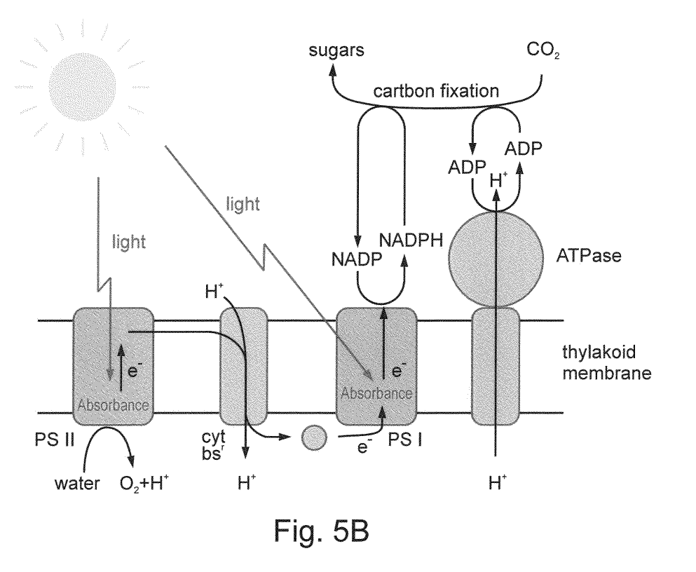

The photosynthetic working rate varies depending on species, light composition, and thus climate, as well as plant health etc. FIG. 5A shows the unmodified photosynthesis process in Eukariotes, and FIG. 5B locates these processes in the thylakoid membrane.

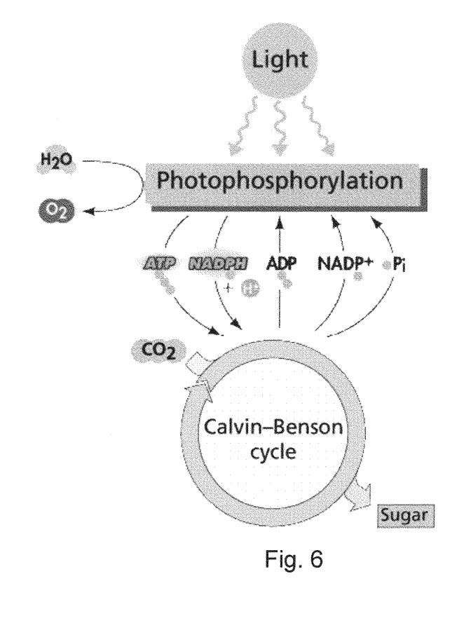

FIG. 6 shows how the excitation products of photophosphorylation can be taken for sugar production.

To synthesize a single sucrose molecule, a simple formula of photosynthesis is as follows (in which E represents the energy of sunlight):

E+6CO2+12H2O=>C6H1206+6H2O+6O2

The energy stored in light establishes a flow of electrons from water (Em=0.82V) to ferredoxin (Em=−0.42V). Formed NADPH is a strong mobile electron carrier that diffuses freely through the stroma to drive the subsequent reduction of CO2 into C3-sugars. Some 690 kJ of light energy are required to drive the transfer of a mole pair of electrons from H2O to NADP+, and some 30% of that energy are conserved in NADPH, and a smaller amount as ATP.

Photosystems are arrangements of chlorophyll and other pigments packed into thylakoids. Many Prokaryotes have only one photosystem, Photosystem II (so numbered because, while it was most likely the first to evolve, it was the second one discovered). Eukaryotes have Photosystem II plus Photosystem I. Photosystem I uses chlorophyll a, in the form referred to as P700. Photosystem II uses a form of chlorophyll a known as P680. Both “active” forms of chlorophyll a function in photosynthesis due to their association with proteins in the thylakoid membrane of the chloroplast.

Photophosphorylation is the process of converting energy from a light-excited electron into the pyrophosphate bond of an ADP molecule. This occurs when the electrons from water are excited by light in the presence of P680. The energy transfer is similar to the chemiosmotic electron transport occurring in the mitochondria. Light energy causes the removal of an electron from a molecule of P680 that is part of Photosystem II. The P680 requires an electron, which is taken from a water molecule, breaking the water into H⁺ ions and O⁻² ions. These O⁻² ions combine to form the diatomic O₂ that is released. The electron is “boosted” to a higher energy state and attached to a primary electron acceptor, which begins a series of redox reactions, passing the electron through a series of electron carriers, eventually attaching it to a molecule in Photosystem I. Light acts on a molecule of P700 in Photosystem I, causing an electron to be “boosted” to a still higher potential. The electron is attached to a different primary electron acceptor (that is a different molecule from the one associated with Photosystem II). The electron is passed again through a series of redox reactions, eventually being attached to NADP⁺ and H⁺ to form NADPH, an energy carrier needed in the Light Independent Reaction. The electron from Photosystem II replaces the excited electron in the P700 molecule. There is thus a continuous flow of electrons from water to NADPH. This energy is used in Carbon Fixation. Cyclic Electron Flow occurs in some eukaryotes and primitive photosynthetic bacteria. No NADPH is produced, only ATP. This occurs when cells may require additional ATP, or when there is no NADP⁺ to reduce to NADPH. In Photosystem II, the pumping of H ions into the thylakoid and the conversion of ADP+P into ATP is driven by electron gradients established in the Noncyclic photophosphorylation (top) and cyclic photophosphorylation (bottom). These processes are better known as the light reactions.

In the above, the P680 protein was manipulated via the associated P680 gene, which has been isolated and sequenced.

The present embodiments provide an artificial genetic modification to take the energy processed in the first phase and transfer 50% thereof to the electrode system and transfer only 50% of the energy to the second phase.

In an alternative embodiment there is provided a nanotechnology-based biometric patch on the top of the plant leaf.

As a third embodiment, the present embodiments provide for drying the genetically modified PS II/I Protein and placing it between two layers of thin glass attached to a semi conductor. Such a method allows for generating with up to 70% efficiency, direct electricity from the free electron released by the photosynthesis effect.

The voltage range of such photosynthetic compounds are presented in Table 1:

TABLE 1
Voltage range of photosynthetic compounds Oxidized Reduced
Number of Electrons Transferred Redox Potential (Volts)

| | | | | | |
|---|---|---|---|---|---|
| X(Fe4S4) | | X□ | | 1 | −0.73 |
| 1/202 | + | H2 | H20 | 2 | +0.82 |

Thus, a potential difference between −0.73 and +0.82=1.55 volt is available in any single step. Such a potential difference is significantly higher than in any photovoltaic cell currently available, whose potential difference is about only 0.5 volt per cell.

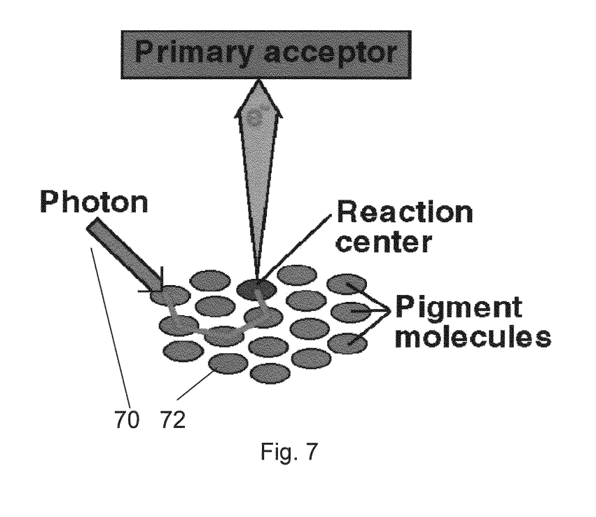

FIG. 7 is a schematic diagram of a monolayer in which photosynthetic material, pigment molecules 70 in reaction centers receive incident photons 72 and produce a charged electron 74.

From an environmental protection point of view, the proposed renewable energy system does produce any net CO2, on the contrary, it produces oxygen and hydrogen, both of which gases can be collected and utilized for other energy dependent processes, ending up with the production of water. The exhausted PS II and E-chain extracts may be collected and transformed to a fertilizer that may be used for crop farming. Thus, this system is more environmentally friendly than any chemical energy conversion known nowadays.

If, two units or n units of leaves or leaf cells or small plants are connected in series, rather than in parallel, then a potential for the crop overall, may accumulate per unit of surface, that is patch size, per leaf, per plant or per the entire the plant field or orchard.

[unit]+[unit]+n[unit]=n{Xn×1.55Volt}

In use, electricity may be obtained directly from plants in the fields. The plants are artificially genetically modified to produce electricity as their main product. Knowledge of the plant's overall ability to generate energy is currently based on a spinach plant which is extremely efficient, churning out considerable energy relative to its size and weight. But combining biological with non-biological materials in one device has proven problematic with researchers in the past. The presently provided genetic engineering allows for relatively simple exploitation of biological material in solar energy conversion in a large scale, cheap and sustainable fashion.

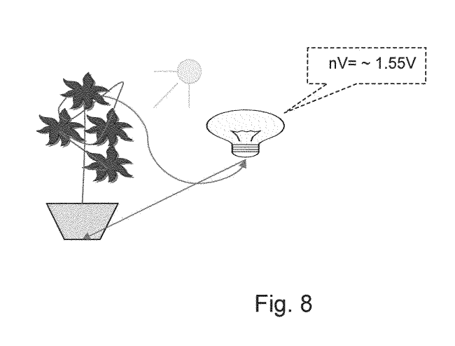

FIG. 8 indicates the use of the present embodiments in microgeneration, that is on the level of the individual consumer. Here a single plant engineered according to the present embodiments powers a light bulb.

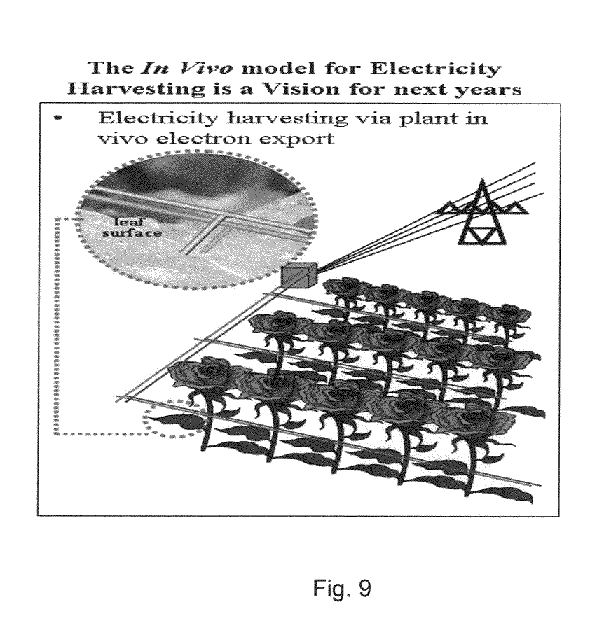

FIG. 9 is a schematic diagram indicating how a field of plants engineered according to the present embodiments may provide an electricity supply to a grid system.

The terms “comprises”, “comprising”, “includes”, “including”, “having” and their conjugates mean “including but not limited to”. This term encompasses the terms “consisting of” and “consisting essentially of”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. Photovoltaic cell apparatus comprising:
a first electrode;
photosynthetic material electrically connected to said first electrode; and
a second electrode electrically connected to said photosynthetic material, said apparatus thereby providing the harvesting of electrons from said photosynthetic material.

2. The apparatus of claim 1, wherein said photosynthetic material is located in a cavity of a semiconductor.

3. The apparatus of claim 1, wherein said second electrode is transparent.

4. The apparatus of claim 1, wherein said photosynthetic material comprises PS I material.

5. The apparatus of claim 4, wherein said photosynthetic material is genetically engineered to pass a first proportion of photosynthesis excitation electrons to said electrodes.

6. The apparatus of claim 5, wherein said photosynthetic material is genetically engineered to retain a second proportion of said photosynthesis excitation electrons for sugar production.

7. The apparatus of claim 2, wherein said cavity is drilled into said semiconductor layer.

8. The apparatus of claim 2, wherein said first electrode is arranged as a grid, reaching a plurality of said cavities about said apparatus.

9. The apparatus of claim 1, wherein said first electrode comprises gold.

10. The apparatus of claim 8, wherein said grid, said cavities and said second electrode are arranged as a first layer therein.

11. The apparatus of claim 10, wherein said grid, said cavities and said second electrode are arranged as a plurality of layers.

12. The apparatus of claim 1, configured for attachment to a growing plant as a patch.

13. The apparatus of claim 1, further comprising a mechanism for collecting released oxygen and hydrogen molecules.
